(19) United States
(12) Patent Application Publication
(10) Pub. No.: US 2006/0105494 A1
(43) Pub. Date: May 18, 2006

(54) METHOD AND APPARATUS FOR CLEANING AND SEALING DISPLAY PACKAGES

(76) Inventors: KAREN HUANG, BOISE, ID (US); CHRISTOPHE PIERRAT, BOISE, ID (US)

Correspondence Address: DALE C. BARR;DORSEY & WHITNEY LLP, U.S. BANK CTR BLDG STE 400, 1400 FIFTH AVENUE, SEATTLE, WA, 981047092, US

(21) Appl. No.: 08/687,117

(22) Filed: Jul. 23, 1996

(51) Int. Cl. H01L 21/50; H01L 21/00

(52) U.S. Cl. 438/106; 438/20; 438/907; 438/908; 134/902

(57) ABSTRACT

A method and apparatus for cleaning and sealing components of a display utilizes continuous isolation of the components between the cleaning step and the sealing step. This limits exposure of the components to contaminants and isolates the components from oxidizing agents which can cause an oxide to form on the surface of one or more of the components. In one embodiment, a high vacuum transfer station couples a cleaning station and a sealing station to allow a component to be transferred from the cleaning station to the sealing station without leaving the high vacuum. In another embodiment, the apparatus includes a conveyor transferring the components from the cleaning station at a high vacuum to the sealing station at a similarly high vacuum without exposure to the atmosphere. Within the cleaning station, the component is cleaned using any of a variety of conventional cleaning techniques, including anisotropic and isotropic etching techniques such as reactive ion etching, plasma etching or vapor hydrofluoric acid etching. A third embodiment employs a single chamber for cleaning and sealing.

### STATEMENT OF GOVERNMENT INTEREST

This invention was made with government support under Contract No. DABT-63-93-C-0025 awarded by Advanced Research Projects Agency (“ARPA”). The government has certain rights in this invention.

### TECHNICAL FIELD

The present invention relates to field emission displays, and more particularly to methods of packaging field emission displays.

### BACKGROUND OF THE INVENTION

Flat panel displays are widely used in a variety of applications, including computer displays. One suitable flat panel display is a field emission display. Field emission displays typically include a generally planar emitter substrate covered by a display screen. A surface of the emitter substrate facing the display screen has formed thereon an array of surface discontinuities projecting toward the display screen. In many cases, the surface discontinuities are conical projections, or “emitters” integral to the substrate. Typically, the emitters are grouped into emitter sets in which the bases of the emitters in each emitter set are commonly connected. Drive electronics may also be integrated into or onto the substrate to control the flow of current to the emitter sets.

A conductive extraction grid is positioned above the emitters and driven with a voltage of about 30-120 V. The emitter drive electronics then selectively ground the emitter sets to provide a current path to ground. The voltage differential between the extraction grid and the grounded emitter sets produces an electric field extending from the extraction grid to the emitters having an intensity that is sufficient to cause the emitter sets to emit electrons.

The display screen is mounted directly above the extraction grid. The display screen is formed from a glass panel coated with a transparent conductive material that forms an anode biased to about 1-2 kV. The anode attracts the emitted electrons, causing the electrons to pass through the extraction grid. A cathodoluminescent layer covers a surface of the anode facing the extraction grid so that the electrons strike the cathodoluminescent layer as they travel toward the 1-2 kV potential of the anode. The electrons strike the cathodoluminescent layer causing the cathodoluminescent layer to emit light at the impact site. Emitted light then passes through the anode and the glass panel where it is visible to a viewer.

Operation and extended lifetime of the emitter substrate typically requires that the emitter substrate be isolated from contaminants, such as moisture or oxidizing agents. The emitter substrate is therefore placed within a package to protect and isolate the emitter substrate. The glass panel carrying the anode acts as a cover for the package and seals to the package to form an airtight body containing the emitter substrate.

Prior to sealing, the emitter substrate is cleaned according to conventional cleaning techniques, such as plasma etching, reactive ion etching or vapor hydrofluoric acid etching. The cleaning process removes contaminants and removes oxidized layers from the emitter substrate. Once the emitter substrate is cleaned, it is removed from the cleaning station and transferred to a sealing station. At the sealing station, the glass substrate of the display screen is bonded to the package to form a sealed, airtight enclosure.

Even though the emitter substrate is typically transferred from the cleaning station to the sealing station in a cleanroom, the emitter substrate and interior of the package are often subjected to contaminants, such as moisture and oxidizing agents. The contaminants can damage the emitter substrate during transfer or after the package has been sealed. Additionally, contaminants in the sealed package detrimentally affect the operation of the field emission display.

Among the particularly problematic contaminants of field emission displays are oxidizing agents, such as oxygen. Oxidizing agents cause surface oxides to form on the emitter substrate and/or on the drive electronics. Such surface oxides can affect the emissive properties of the emitters and can impair operation of the drive electronics.

### SUMMARY OF THE INVENTION

A method and apparatus for cleaning and sealing a package containing an emitter substrate continuously maintains the emitter substrate and package in a contaminant-free environment from the completion of the cleaning through the sealing of the package. In one embodiment of the apparatus according to the invention, separate cleaning and sealing stations are coupled through a transfer station. Each of the cleaning, sealing, and transfer stations is in a high vacuum chamber having a vacuum port to allow pumping of the chamber. The embodiment also includes a load lock chamber linked to the transfer station to allow transfer of packages into the transfer station.

In a method according to this embodiment, housings containing emitter arrays are placed in the first load lock chamber. Then, the first load lock chamber is pumped to a high vacuum level. When the load lock chamber reaches the high vacuum level, the housings pass through a high vacuum link to the transfer station. The transfer station is then pumped to remove any contaminants, such as oxidizing agents.

The housings then pass through a second link to the cleaning station where they are cleaned in a high vacuum. During, and at the completion of cleaning, the cleaning station is pumped to remove any additional contaminants, such as cleaning byproducts.

After the housings and emitter arrays are cleaned, they pass through the second link to the transfer station and then through a third link to the sealing station. Within the sealing station, covers are placed atop the housings and sealed to form sealed packages containing the emitter arrays. Because the cleaning, transfer, and sealing stations are maintained at high vacuum, the arrays are maintained in a contaminant-free environment from the completion of cleaning through the sealing of the packages. Once the packages are sealed, they return through the third link to the transfer station. The sealed packages then move to the load lock chamber. The load lock chamber is then raised to atmospheric pressure and the sealed packages are removed.

In a second embodiment of the apparatus according to the invention, a conveyor system transports packages through a cleaning station and a sealing station that is directly linked to the cleaning station through a high vacuum link. A first load lock chamber provides access for packages to enter the cleaning station and a second load lock chamber allows access for packages to exit the sealing station.

In a method according to this embodiment, housings containing emitter substrates enter the first load lock chamber. Then the first load lock chamber is reduced to a high vacuum level and the housings are transferred to the cleaning station. When the emitter substrates are in the cleaning station, a cleaning gas or vapor is introduced to clean the housings and emitter substrates. Before completion of the cleaning step, the cleaning station is pumped to a high vacuum and substantially all contaminants are removed from the cleaning station. Then, the housings and emitter substrates are transferred to the sealing station where covers are attached and sealed to form sealed packages. The sealed packages then exit the sealing station to the second load lock chamber. Finally, the second load lock chamber is raised to atmospheric pressure, and the sealed packages are removed.

A third embodiment of the apparatus according to the invention includes a single station that operates as both a cleaning and sealing station. Load lock chambers coupled to the cleaning and sealing stations allow insertion of housings and covers and removal of sealed packages. In a method according to this embodiment, housings and emitter substrates enter the first load lock chamber, and the first load lock chamber is pumped to a high vacuum level. Covers enter the second load lock chamber, and the second load lock chamber is pumped to approximately the same high vacuum level. The covers, housings and emitter substrates then enter the cleaning and sealing station, which is also at the high vacuum level. Within the cleaning and sealing station the emitter substrate is first cleaned. Before completing the cleaning process, the cleaning and sealing station is pumped again to remove contaminants, such as oxidizing agents and cleaning byproducts. While the covers, housings and emitter substrates are within the cleaning and sealing station, the covers are attached to the housings and sealed to form sealed packages. The sealed packages are removed through the third load lock chamber.

### BRIEF DESCRIPTION OF THE DRAWINGS

FIG. 1 is a block diagram of a first embodiment of a cleaning and sealing system according to the invention including a transfer station.

FIG. 2 is a flowchart presenting processing steps in cleaning and sealing a package according to the invention.

FIG. 3 is a block diagram of a cleaning and sealing apparatus according to the invention, including a conveyer.

FIG. 4A is a side cross-sectional view of an emitter array mounted in the housing of a display package.

FIG. 4B is a side cross-sectional view of a display screen bonded to a display housing to form a sealed display package.

FIG. 5 is a block diagram of a third embodiment of a cleaning and sealing system according to the invention including a combined cleaning and sealing station.

### DETAILED DESCRIPTION OF THE INVENTION

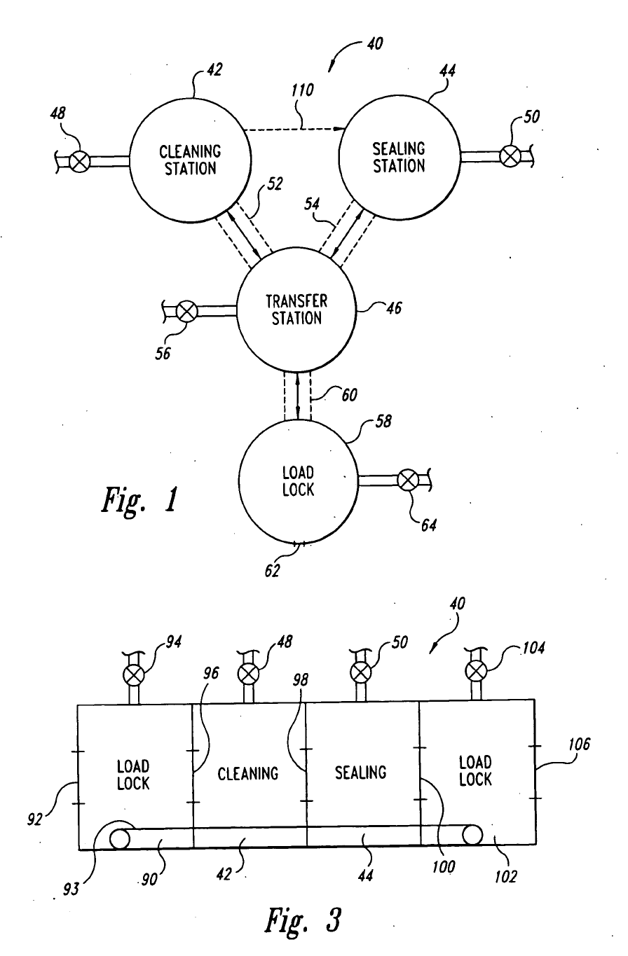

As shown in FIG. 1, a package sealing system 40 includes a cleaning station 42 and a sealing station 44 linked by a transfer station 46. The cleaning station 42 is a conventional integrated circuit cleaning structure, such as a plasma-etching chamber, reactive-ion etching chamber or by vapor hydrofluoric acid etching. To allow cleaning at extremely low pressure, the cleaning station 42 is vacuum sealable, and includes a vacuum port 48 at which a high vacuum, typically about 0.01-300 mTorr, can be applied through conventional vacuum pumping. As will be discussed below, the cleaning station 42 is typically maintained at a high vacuum during normal operation.

The sealing station 44 is of a conventional type allowing packages to be sealed in a vacuum. To allow sealing at a high vacuum, the sealing station 44 includes a vacuum port 50 to which a high vacuum can be applied through conventional vacuum pumping. Like the cleaning station, the sealing station is maintained at high vacuum during normal operation.

The cleaning station 42 and sealing station 44 are linked to each other by a transfer station 46. The transfer station 46 is a high vacuum sealable chamber linked to each of the cleaning station 42 and sealing station 44 by respective high vacuum links 52, 54. Like the cleaning and sealing stations 42, 44, the transfer station 46 also includes a vacuum port 56 to allow the transfer station to be pumped to a high vacuum.

The links 52, 54 are conventional links between high vacuum chambers, such as resealable passageways. One skilled in the art will recognize a variety of structures and methods for transferring parts between the transfer station 46 and the cleaning and sealing stations 42, 44 while maintaining a vacuum. For example, the transfer station 46 may include “turntable” structures or conveyer systems linking the stations 42, 44. The turntables or conveyor systems transport the parts along the vacuum sealed passageways forming the links 52, 54. Typically, the links 52, 54 include resealable doors to isolate the stations 42, 44, 46 before and after transfer of parts.

In addition to the stations 42, 44, 46, the sealing system 40 also includes a load lock chamber 58 linking the transfer station 46 to the external atmosphere. The load lock chamber 58 is a conventional load lock chamber linked to the transfer station 46 through a high vacuum link 60. The load lock chamber 58 also has an insertion port 62 for inserting parts. The load lock chamber 58, like the stations 42, 44, 46, further includes a vacuum port 64 to allow the load lock chamber 58 to be pumped to a high vacuum.

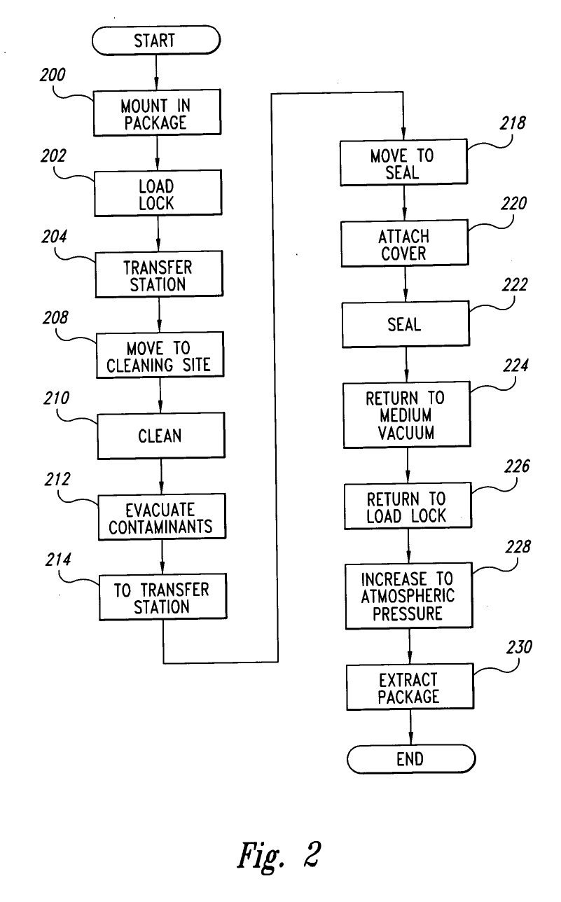

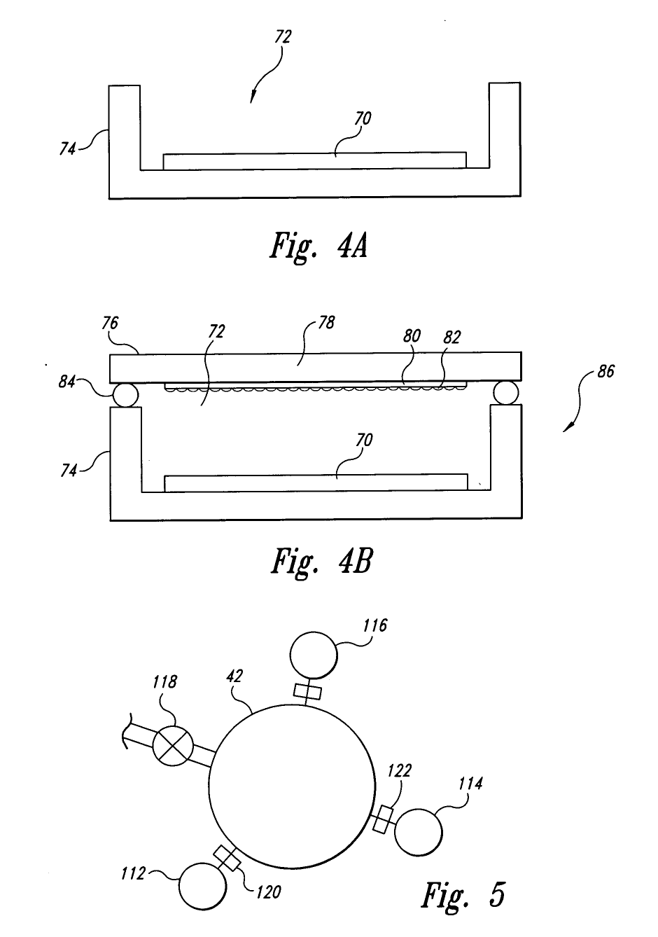

Operation of the sealing system 40 of FIG. 1 is best explained with reference to the flowchart of FIG. 2 and the cross sectional representations of a display 68 in FIGS. 4A and 4B. Prior to reaching the sealing system 40, an emitter substrate 70 is mounted in a recess 72 in a display housing 74, as represented in step 200 of FIG. 2 and shown in FIG. 4A. The housing 74 containing the emitter substrate 70 is then transferred to the load lock chamber 58 (FIG. 1) which is pumped down to a high vacuum. The transfer station 46 is also at the high vacuum at this point.

Once the load lock chamber 58 reaches the high vacuum and the pressures in the load lock chamber 58 and transfer station 46 are about equal, the housing 74 and substrate 70 are transferred through the link 60 to the transfer station 46 in step 204. As noted above, the cleaning station 42 is also at a high vacuum. Once the transfer station 46 reaches the high vacuum and the pressures in the transfer station 46 and cleaning station 42 are about equal, the housing 74 and substrate 70 are transferred to the cleaning station 42 through the link 52 in step 208. Within the cleaning station 42, the substrate 70 and housing 74 are cleaned according to conventional techniques, such as plasma etching, reactive ion etching or vapor hydrofluoric acid etching. During, and at the completion of, the cleaning process, the cleaning station 42 is pumped down through the vacuum port 48 to evacuate contaminants, such as cleaning byproducts, residue, oxides, and/or cleaning agents, in step 212.

At the completion of cleaning, the housing 74 and substrate are transferred through the link 52 from the cleaning station 42 to the transfer station 46 in step 214. Then, the housing 74 and substrate 70 are transferred through the link 54 from the transfer station 46 to the sealing station 44 in step 218. Because the cleaning station 42, transfer station 46, and sealing station 44 are all at high vacuum, these transfers occur with substantially complete isolation from the outside atmosphere. Consequently, the emitter substrate 70 is not exposed to oxidizing agents, such as contaminants or oxygen in the air. The substrate 70 thus does not develop surface oxides that can impair its performance. Moreover, because the system incorporates the load lock chamber 58, the stations 42, 44, 46 are not vented to the outside environment, further reducing risk of exposure to contaminants.

Within the sealing station 44, a transparent cover 76 is placed atop the housing 74 in step 220. As shown in FIG. 4B, the cover 76 is formed from a glass plate 78 having a transparent anode 80 and cathodoluminescent layer 82 on an inner surface. In step 222, the cover 76 is bonded to the housing 74 with a bonding agent 84 that may be a glass solder or frit, or other conventional bonding agent. The sealed cover 76 and housing 74 thus form a sealed package 86. Because sealing occurs within the evacuated sealing station 44, the interior of the sealed package 86 is also evacuated. Consequently, the array 70 remains continuously isolated from contaminants between the cleaning step 212 and the sealing step 224.

Once the package 86 is sealed, the package 86 passes through the link 54 to the transfer station 46 in step 224, and then through the link 60 to the load lock chamber 58. The pressure in the load lock chamber 58 is then increased to atmospheric pressure in step 228, and the package 86 is removed from the load lock 58 through the insertion port 62 in step 230.

FIG. 3 shows another embodiment of the package sealing station 40 according to the invention in which packages pass linearly through the sealing station 40 in a conveyor-like approach. The sealing system 40 includes an input lock chamber 90, the cleaning station 42, the sealing station 44, and an output load lock chamber 102 all sequentially coupled by respective links 96, 98, 100. Each of the load lock chambers 90, 102 includes a respective variable vacuum port 94, 104 and each of the stations 42, 44 includes a respective high vacuum port 48, 50.

In the embodiment of FIG. 3, the housings 74 (FIG. 4A) containing the emitter substrates 70 enter the input load lock chamber 90 through an insertion port 92. The input load lock chamber 90 is then pumped to the high vacuum level through the vacuum port 94. When the first load lock chamber 90 reaches the high vacuum level, the housing 74 and substrate 70 are transferred on a conveyor system 93 through the high vacuum link 96 to the cleaning station 42. The substrate 70 is then cleaned, as described above.

Once the substrate 70 is cleaned, the housing 74 and substrate 70 are conveyed through a high vacuum link 98 into the sealing station 44. The sealing station 44 has previously been pumped to a high vacuum through the vacuum port 50 so that the housing 74 and substrate 70 undergo little or no pressure change when passing through the link 98. Within the sealing station 44, the cover 76 (FIG. 4B) is placed over the housing 70. The package 86 is then sealed as described above.

Once the package 86 is sealed, the package 86 is conveyed through a vacuum link 100 to a second load lock chamber 102. The pressure in the output load lock chamber 102 is then reduced to atmospheric pressure through a vacuum port 104. Once the load lock chamber 102 reaches atmospheric pressure, the package 86 is removed through an extraction port 106. This system 40 advantageously eliminates the high vacuum transfer station 46 of the embodiment of FIG. 1.

In a third embodiment of the invention, shown in FIG. 5, the packages 86 are both cleaned and sealed at the cleaning station 42. This system 40 includes the cleaning station 42 as the central unit. Three load lock chambers 112, 114, 116 provide access to the cleaning station 42, and a vacuum port 118 allows the cleaning station 42 to be pumped to a high vacuum level.

In operation, the first load lock chamber 112 is initially open to the atmosphere. Housings 74 and substrates 70 (FIG. 4A) are placed in the first load lock chamber 112, and the first load lock chamber 112 is pumped to a high vacuum. At about the same time, covers 76 are placed in the second load lock chamber 114. The second load lock chamber 114 is then pumped to a high vacuum.

Once the first and second load lock chambers 112, 114 reach the high vacuum, the housings 74 and substrates 70 are transferred through a first link 120 to the cleaning station 42. Covers 76 are transferred into the cleaning station 42 through a second link 122. In the cleaning station 42, the substrates 70 are cleaned as described above. During, and at the completion of cleaning, the cleaning station 42 is pumped down through the vacuum port 118 to a high vacuum to evacuate contaminants.

When cleaning is complete, the covers 76 are placed on the housings 74, and the packages 86 are sealed as described above. Then, the sealed packages 86 are transferred to the third load lock chamber 116, which is also at a high vacuum. The third load lock chamber 116 is then raised to atmospheric pressure, and the packages 86 are removed.

From the foregoing, it will be appreciated that, although embodiments of the invention have been described herein for purposes of illustration, various modifications may be made without deviating from the spirit and scope of the invention. For example, in the embodiment of FIG. 1, housings 74 may be transferred from the cleaning station 42 directly to the sealing station 44 through a direct path 110 (represented by the broken line in FIG. 1) which may be an additional high vacuum link. Also, the cleaning step 212 has been described as reactive ion etching, plasma etching or vapor hydrofluoric acid etching. However, various other contaminant removal steps may be within the scope of the term cleaning. For example, steps such as rinsing with a cleansing or etching solution, ion milling, or various forms of isotropic or anisotropic etching would be within the scope of the term cleaning. Also, although the packages 86 have been described as being sealed in a high vacuum, one skilled in the art will understand that the packages 86 can be sealed in a different controlled environment. For example, selected contaminant-free gases, such as noble gases or nitrogen can be added to the sealing station 44 to equalize pressure across the cover 76 for some applications. Accordingly, the invention is not limited except as by the appended claims.

1. A method of producing a field emission display having an emitter substrate and a cover, comprising the steps of:
positioning the emitter substrate in a cleaning station through a first load lock chamber;
cleaning the emitter substrate;
before completing the step of cleaning the emitter substrate, forming a vacuum at the cleaning station such that the emitter substrate is subjected to the vacuum;
while maintaining the vacuum, transferring the emitter substrate to a sealing station;
positioning the cover into the sealing station through a second load lock chamber; and
sealing the cover over the emitter substrate to form a sealed unit while maintaining the vacuum on the emitter substrate between the time that the vacuum is formed at the cleaning station and sealing of the emitter substrate has been completed.

2. The method of claim 1 wherein the step of forming a vacuum at the cleaning station begins before the step of cleaning the emitter substrate.

3. The method of claim 1, further including the step of pumping down the cleaning station after cleaning to remove contaminants.

4. The method of claim 3 wherein the step of cleaning the emitter substrate in the vacuum includes adding a cleaning substance to the vacuum to remove a surface oxide or other contamination, and the step of pumping down the cleaning station includes, after removing the surface oxide, removing residual cleaning substance.

5. The method of claim 1 wherein the step of cleaning the emitter substrate in the vacuum includes reactive ion etching.

6. The method of claim 1 wherein the step of cleaning the emitter substrate in the vacuum includes plasma etching.

7. A method of sealing an emitter substrate of a field emission display, comprising the steps of:
applying a vacuum to the emitter substrate;
while maintaining the vacuum, positioning the emitter substrate in an evacuated station using a conveyor system;
removing contaminants from the substrate while the vacuum is applied; and
sealing the emitter substrate before removing the vacuum such that the vacuum is maintained continually between the completion of the step of removing the contaminants and completion of the step of sealing the emitter substrate.

8. The method of claim 7 wherein the step of removing contaminants from the emitter substrate while the vacuum is applied includes:
adding a cleaning substance to the emitter substrate with the vacuum applied to remove a surface oxide or other contamination; and
after removing the surface oxide, pumping the vacuum to remove cleaning byproducts.

9. The method of claim 8 wherein the step of adding a cleaning substance to the vacuum includes adding an etchant to the vacuum.

10. The method of claim 8 wherein the step of cleaning the emitter substrate further includes the step of producing a plasma to etch the emitter substrate while the vacuum is applied.

11. A method of sealing a package containing an emitter substrate, comprising the steps of:
positioning the emitter substrate within an evacuated chamber through a first load lock chamber;
positioning a cover within the evacuated chamber through a second load lock chamber;
cleaning the emitter substrate while the emitter substrate is positioned within the evacuated chamber;
during the step of cleaning the emitter substrate, continuously applying a vacuum to the emitter substrate to remove cleaning byproducts;
after the step of cleaning the emitter substrate, sealing the cover of the package with the emitter substrate therein while the emitter substrate is positioned within the evacuated chamber; and
continuously isolating the package from oxidizing agents between the step of continuously applying a vacuum and the step of sealing the cover of the package.

12. The method of claim 11 wherein the step of continuously applying a vacuum to the emitter substrate includes the step of producing a vacuum containing the package.

13. The method of claim 11 wherein the step of continuously applying a vacuum to the emitter substrate further includes the step of producing a plasma to etch the emitter substrate.

14. The method of claim 11 wherein the step of continuously applying a vacuum to the emitter substrate further includes the step of adding a cleaning substance to the emitter substrate with the vacuum applied to remove a surface oxide; and
while removing the surface oxide, removing cleaning byproducts.

15. The method of claim 14 wherein the step of adding a cleaning substance to the vacuum includes adding an etchant.

16. The method of claim 14 wherein the step of removing cleaning byproducts includes pumping down the vacuum.

17. An apparatus for packaging an emitter substrate, comprising:
a cleaning chamber; a sealing chamber;
a vacuum source coupled to the cleaning chamber. and the sealing chamber to produce a vacuum therein; and
a link between the cleaning chamber and the sealing chamber, the link being configured to maintain the vacuum as the emitter panel is transferred from the cleaning chamber to the sealing chamber.

18. The apparatus of claim 17, further including:
an input load lock chamber coupled to the cleaning chamber;
a first vacuum pump coupled to produce a first vacuum level in the input load lock chamber; and
a second vacuum pump coupled to produce a second vacuum level in the cleaning chamber.

19. The apparatus of claim 18 wherein the first and second vacuum levels are the same.

20. The apparatus of claim 17, further including:
an output load lock chamber; and
a conveyor for sequentially transferring the emitter substrate from the input load lock chamber to the cleaning chamber, the sealing chamber, and the output load lock chamber.

21. An apparatus for packaging an emitter substrate, comprising:
a sealed transfer station;
a cleaning chamber;
a first link between the transfer station and the cleaning chamber;
a sealing chamber; and
a second sealed link between the transfer station and the sealing chamber.

22. The apparatus of claim 21 wherein the transfer station includes a turntable.

23. The apparatus of claim 21 wherein each of the cleaning chamber and the sealing chamber include vacuum ports.

24. The method of claim 1, further comprising the step of removing the sealed unit from the sealing station through a third load lock chamber.

25. The method of claim 1 wherein the step of positioning the emitter substrate in a cleaning station through a first load lock chamber includes positioning the emitter substrate in a cleaning station using a conveyor system.

26. The method of claim 7, further comprising:
positioning the emitter substrate in the evacuated station through a first load lock chamber; and
positioning a cover in the evacuated station through a second load lock chamber;
and wherein the step of sealing the package includes sealing the cover over the emitter substrate while maintaining the vacuum.

27. The method of claim 26, further comprising the step of removing the sealed package from the evacuated station through a third load lock chamber.

28. The method of claim 7 wherein the steps of removing contaminants from the substrate and sealing the emitter substrate occur at the same location within the evacuated station.

29. (canceled)

30. The method of claim 11, further comprising the step of removing the sealed package from the evacuated station through a third load lock chamber.

31. The method of claim 11 wherein the step of positioning the emitter substrate within an evacuated chamber through a first load lock chamber includes positioning the emitter substrate within an evacuated chamber using a conveyor system.

32-33. (not entered)
